(19) United States
(12) Patent Application Publication
(10) Pub. No.: US 2015/0149103 A1
(43) Pub. Date: May 28, 2015

(54) MAGNETIC BODY ANALYZING DEVICE AND MAGNETIC BODY ANALYZING METHOD

(71) Applicant: FUJITSU LIMITED, Kawasaki-shi (JP)

(72) Inventor: Koichi Shimizu, Inagi (JP)

(21) Appl. No.: 14/499,292

(22) Filed: Sep. 29, 2014

(30) Foreign Application Priority Data
Nov. 27, 2013 (JP) 2013-245432

(51) Int. Cl. G01N 27/72; G01R 33/06

(52) U.S. Cl. CPC G01N 27/72; G01R 33/06
USPC 702/65

(57) ABSTRACT

A magnetic body analyzing device includes a change amount calculation unit that calculates a change amount by which magnetization vectors arranged on an analysis target change for a predetermined period of time every time the predetermined period of time passes, a change amount cumulating unit that cumulates respective change amounts of the magnetization vectors calculated for each predetermined period of time every time the predetermined period of time passes, a change amount determination unit that determines whether a cumulated value of the cumulated change amounts of the magnetization vectors exceeds a predetermined change width, and a storing unit that records, in a storage unit, the magnetization vectors at a time point at which the cumulated value exceeds the change width when it is determined that the cumulated value exceeds the change width.

### CROSS-REFERENCE TO RELATED APPLICATION(S)

This application is based upon and claims the benefit of priority of the prior Japanese Patent Application No. 2013-245432, filed on Nov. 27, 2013, the entire contents of which are incorporated herein by reference.

### FIELD

The embodiments discussed herein are related to a magnetic body analyzing device and a magnetic body analyzing method.

### BACKGROUND

When a magnetization structure of a magnetic body on a small region of equal to or smaller than a micrometer (μm) is analyzed numerically, an analyzing method called micromagnetic analysis is used. In the micromagnetic analysis, a Landau-Lifshitz-Gilbert (LLG) equation of magnetization vectors in which a plurality of magnetization vectors are unknown values is solved so as to calculate time change of the magnetization vectors. The analyzing method is transient calculation depending on time and the magnetization vectors change as time passes. The magnetization vector herein is, in the micromagnetic analysis, an unknown value in the LLG equation and is a vector value defined for an individual element of a mesh that is used in a finite element method or a finite difference method, for example.

In the conventional micromagnetic analysis, when a value of a time interval at which the magnetization vectors are stored is set and calculation is started, pieces of data of the magnetization vectors are stored at the set constant time interval.

Examples of the conventional techniques are described in Japanese Laid-open Patent Publication No. 2005-83764, Japanese Laid-open Patent Publication No. 2004-110212, and International Publication Pamphlet No. WO 2005/057434.

In the conventional micromagnetic analysis, the pieces of data of the magnetization vectors are stored at a constant time interval. This arises a problem that the pieces of data of the magnetization vectors are not stored efficiently. For example, when a change rate of the magnetization vectors with respect to time is non-uniform, that is, when a time region in which the magnetization vectors do not change and a time region in which the magnetization vectors change drastically are mixed, the pieces of data of the magnetization vectors are not stored efficiently. The problem in this case will be described with reference to FIG. 8 and FIG. 9.

FIG. 8 is a graph illustrating change of the magnetization vectors and a storing timing when a storing time interval is long. As illustrated in FIG. 8, when pieces of data of the magnetization vectors are stored at a constant time interval (storing time interval), the sufficient number of pieces of data of the magnetization vectors in a process during which the magnetization vectors largely change for a short period of time (change is drastic) are not stored.

FIG. 9 is a graph illustrating change of the magnetization vectors and the storing timing when the storing time interval is short. As illustrated in FIG. 9, when pieces of data of the magnetization vectors are stored at a constant time interval (storing time interval), the magnetization vectors in the process during which the magnetization vectors largely change for a short period of time (change is drastic) can be stored. Most of the magnetization vectors that are stored are, however, unchanging values. Due to this, a large number of pieces data of the magnetization vectors are stored wastefully.

The above-mentioned problem arises not only in the micromagnetic analysis but also in analysis of a magnetic body of which magnetization vectors change as time passes.

### SUMMARY

According to an aspect of an embodiment, a magnetic body analyzing device includes a processor and a memory. The processor executes calculating a change amount by which magnetization vectors arranged on an analysis target change for a predetermined period of time every time the predetermined period of time passes when a magnetic body is analyzed. The processor executes cumulating respective change amounts of the magnetization vectors calculated for each predetermined period of time at the calculating every time the predetermined period of time passes. The processor executes determining whether a cumulated value of the change amounts of the magnetization vectors cumulated at the cumulating exceeds a predetermined change width. The processor executes recording, in the memory, the magnetization vectors of a time point at which the cumulated value exceeds the change width when the determining determines that the cumulated value exceeds the change width.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a functional block diagram illustrating the configuration of a magnetic body analyzing device according to an embodiment;

FIG. 2 is a graph for explaining a unit magnetization vector, a sum of change amounts, and a storing timing in the embodiment;

FIG. 3 is a view illustrating an example of result data in the embodiment;

FIG. 4 is a view illustrating a flowchart of magnetization vector storing processing in the embodiment;

FIG. 5 is a view illustrating a flowchart of result output processing in the embodiment;

FIG. 6A is a first view illustrating an example of transition of magnetization change of magnetization vectors (Y-axis component);

FIG. 6B is a second view illustrating an example of the transition of the magnetization change of the magnetization vectors (Y-axis component);

FIG. 7 is a diagram illustrating an example of a computer that executes a magnetic body analyzing program;

FIG. 8 is a graph illustrating change of the magnetization vectors and a storing timing (when storing time interval is long); and

FIG. 9 is a graph illustrating change of the magnetization vectors and the storing timing (when storing time interval is short).

### DESCRIPTION OF EMBODIMENT

Preferred embodiments of the present invention will be explained with reference to accompanying drawings. The following embodiment describes the case in which the invention is applied to micromagnetic analysis. The invention is not limited by the embodiment and can be widely applied to magnetic body analysis.

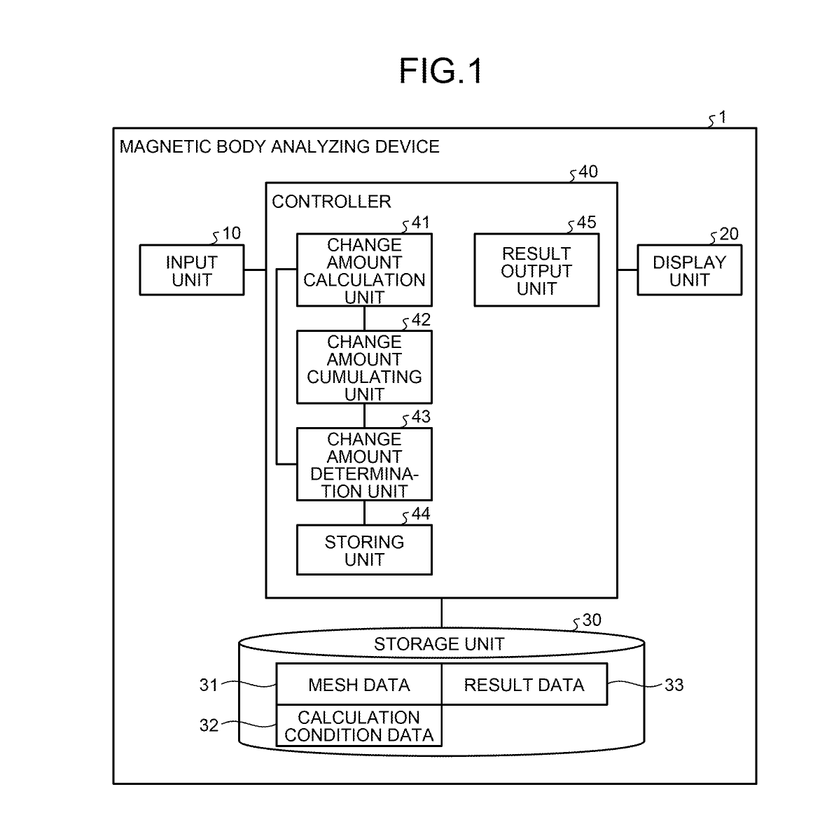

FIG. 1 is a functional block diagram illustrating the configuration of the magnetic body analyzing device according to the embodiment. As illustrated in FIG. 1, a magnetic body analyzing device 1 includes an input unit 10, a display unit 20, a storage unit 30, and a controller 40.

The magnetic body analyzing device 1 stores pieces of data of magnetization vectors that change as time passes in accordance with a change amount of the magnetization vectors when a magnetic body is analyzed. That is to say, when the magnetization vectors change moderately, the magnetic body analyzing device 1 increases a time interval at which it stores the pieces of data of the magnetization vectors in accordance with the change amount. In contrast, when the magnetization vectors change drastically, the magnetic body analyzing device 1 decreases the time interval at which it stores the pieces of data of the magnetization vectors in accordance with the change amount. The magnetic body analyzing device 1 visualizes the stored pieces of data of the magnetization vectors based on the time interval (storing time interval) at which the pieces of data are stored. The magnetization vector indicates a vector value defined for an individual element of a mesh that is used in a finite element method or a finite difference method, for example, in the micromagnetic analysis. Time referred in the embodiment indicates time in a space of a physical phenomenon as a simulation target of the magnetic body analysis.

The input unit 10 is an input device with which a user performing analysis inputs various pieces of information and directions to the magnetic body analyzing device 1. For example, the input unit 10 corresponds to a keyboard, a mouse, or a touch panel. The display unit 20 is a display device displaying various pieces of information. For example, the display unit 20 corresponds to a display or a touch panel.

The storage unit 30 is a semiconductor memory device such as a random access memory (RAM) and a flash memory or a storage device such as a hard disk and an optical disk, for example. The storage unit 30 stores therein mesh data 31, calculation condition data 32, and result data 33. The mesh data 31 is data formed by a plurality of elements obtained by dividing a region of a magnetic body as an analysis target into the finite number by the finite element method or the finite difference method. The element is a region of a minimum unit obtained by dividing the region as the analysis target and is constituted by a plurality of nodal points. The calculation condition data 32 is data relating to calculation conditions of the magnetic body analysis. The calculation condition data 32 contains the number of individual elements of the mesh that is used in the finite element method or the finite difference method and a value of a change amount width, which will be described later. It is to be noted that a data format of the result data 33 will be described later.

The controller 40 corresponds to an electronic circuit of an integrated circuit such as an application specific integrated circuit (ASIC) and a field programmable gate array (FPGA), for example. The controller 40 corresponds to an electronic circuit such as a central processing unit (CPU) and a micro processing unit (MPU). The controller 40 includes an internal memory for storing therein computer programs and pieces of control data defining various pieces of processing procedures and executes various pieces of processing thereby. For example, the controller 40 executes magnetic body analyzing processing. In the magnetic body analyzing processing, the mesh data 31 and the calculation condition data 32 are read from the storage unit 30 and calculation is started. Then, in the magnetic body analyzing processing, the magnetization vectors are arranged on the respective elements of the mesh data 31 and the arranged magnetization vectors are stored in the storage unit 30 as pieces of field data in a process of transient calculation.

The controller 40 includes a change amount calculation unit 41, a change amount cumulating unit 42, a change amount determination unit 43, a storing unit 44, and a result output unit 45.

The change amount calculation unit 41 calculates a change amount by which the magnetization vectors arranged on the analysis target have changed for a predetermined period of time every time the predetermined period of time passes between the start of the analysis and the end of the analysis when the magnetic body is analyzed. The predetermined period of time herein indicates a time interval width in time that is referred in the magnetic body analysis. For example, the change amount calculation unit 41 calculates the change amount of unit magnetization vectors at a time point just after time for the time interval width has passed. The unit magnetization vector herein indicates a value obtained by dividing the magnetization vector by a saturated magnetic flux density. In other words, the unit magnetization vector is a vector obtained by normalizing the magnitude of the magnetization vector to 1.

As an example, the change amount calculation unit 41 calculates a change amount dmₛᵤₘⁱ of the unit magnetization vectors at a time point i by using an equation (1).

$$d {m}_{sum}^{i} = \frac{{\sum }_{j = 1}^{N} \vert d {m}_{j}^{i} \vert}{N} \qquad ( 1 )$$

dmₛᵤₘⁱ in the equation (1) is an average value of absolute values of the change amounts of the unit magnetization vectors arranged on all the elements (or nodal points) of the mesh data 31 at the time point i. The change amount dmⱼⁱ is an amount by which a physical amount of the unit magnetization vector of a j^{th} element (or nodal point) changes between a time point i−1 and the time point i. The change amount dmⱼⁱ is expressed by the absolute value of the changed vector as indicated by an equation (2) because it is obtained for the vector.

$${m}_{sum} = 100 \times {\sum }_{i = 1}^{T} d {m}_{sum}^{i} = 100 \times \frac{{\sum }_{i = 1}^{T} {\sum }_{j = 1}^{N} \vert d {m}_{j}^{i} \vert}{N} \qquad ( 4 )$$

The unit magnetization vectors obtained by normalizing the magnitudes of the magnetization vectors to 1 are used, so that the change amount can be defined in percentage.

The equation (2) is converted into an equation (3) when expressed by x, y, and z components.

$$\vert d {m}_{j}^{i} \vert = \vert {\vec{m}}_{j}^{i} - {\vec{m}}_{j}^{i - 1} \vert = \sqrt{{( {\vec{m}}_{j}^{i} - {\vec{m}}_{j}^{i - 1} )}^{2}} \qquad ( 2 )$$

The change amount cumulating unit 42 cumulates respective change amounts of the magnetization vectors calculated for each predetermined period of time every time the predetermined period of time passes. For example, the change amount cumulating unit 42 adds the change amount of the unit magnetization vectors calculated at the time point just after time for the time interval width has passed by the change amount calculation unit 41 to the sum of the change amounts of the unit magnetization vectors calculated before. As an example, the change amount cumulating unit 42 calculates the sum of the change amounts of the unit magnetization vectors to a time point T by using an equation (4).

$$\sqrt{{( {\vec{m}}_{j}^{i} - {\vec{m}}_{j}^{i - 1} )}^{2}} = \sqrt{{( {m}_{j , x}^{i} - {m}_{j , x}^{i - 1} )}^{2} + {( {m}_{j , y}^{i} - {m}_{j , y}^{i - 1} )}^{2} + {( {m}_{j , z}^{i} - {m}_{j , z}^{i - 1} )}^{2}} \qquad ( 3 )$$

The sum of the change amounts can be defined in percentage by using the unit magnetization vectors obtained by normalizing the magnitudes of the magnetization vectors to 1. The sum of the change amounts can be defined by percent (%) by multiplying it by 100 as indicated in the equation (4).

The change amount determination unit 43 determines whether a cumulated value of the change amounts of the magnetization vectors exceeds a change amount width. The change amount width is used for determining a storing timing. It is to be noted that a user defines the change amount width previously. For example, the change amount determination unit 43 determines whether the sum obtained by cumulating the change amounts of the unit magnetization vectors at the respective time points by the change amount cumulating unit 42 exceeds the change amount width. When the change amount determination unit 43 determines that the sum exceeds the change amount width, the change amount determination unit 43 passes the process to the storing unit 44 in order to store the magnetization vectors at the time point at which the sum exceeds the change amount width.

When the storing unit 44, which will be described later, stores the magnetization vectors at the time point at which the sum exceeds the change amount width, the change amount determination unit 43 determines whether a cumulated value of change amounts of magnetization vectors after the time point at which the sum exceeds the change amount width exceeds the change amount width newly. If the change amount determination unit 43 determines that the cumulated value exceeds the change amount width, the change amount determination unit 43 passes the process to the storing unit 44 in order to store the magnetization vectors at the time point at which the cumulated value exceeds the change amount width. If the change amount determination unit 43 determines that the cumulated value does not exceed the change amount, the change amount determination unit 43 passes the process to the change amount calculation unit 41 in order to calculate a change amount of the magnetization vectors at a subsequent time point.

When the cumulated value of the change amounts of the magnetization vectors exceeds the change amount width, the storing unit 44 stores, in the result data 33, the magnetization vectors at the time point at which the cumulated value exceeds the change amount width. For example, when the change amount determination unit 43 determines that the cumulated value exceeds the change amount width, the storing unit 44 stores, in the result data 33, the unit magnetization vectors at the time point at which the cumulated value exceeds the change amount width and a period of time from the time point at which the cumulated value exceeds the change amount width at the previous time to the time point at which the cumulated value exceeds the change amount width at this time in a correspondence manner. The period of time is referred to as “storing time interval”.

Unit Magnetization Vector Storing Timing

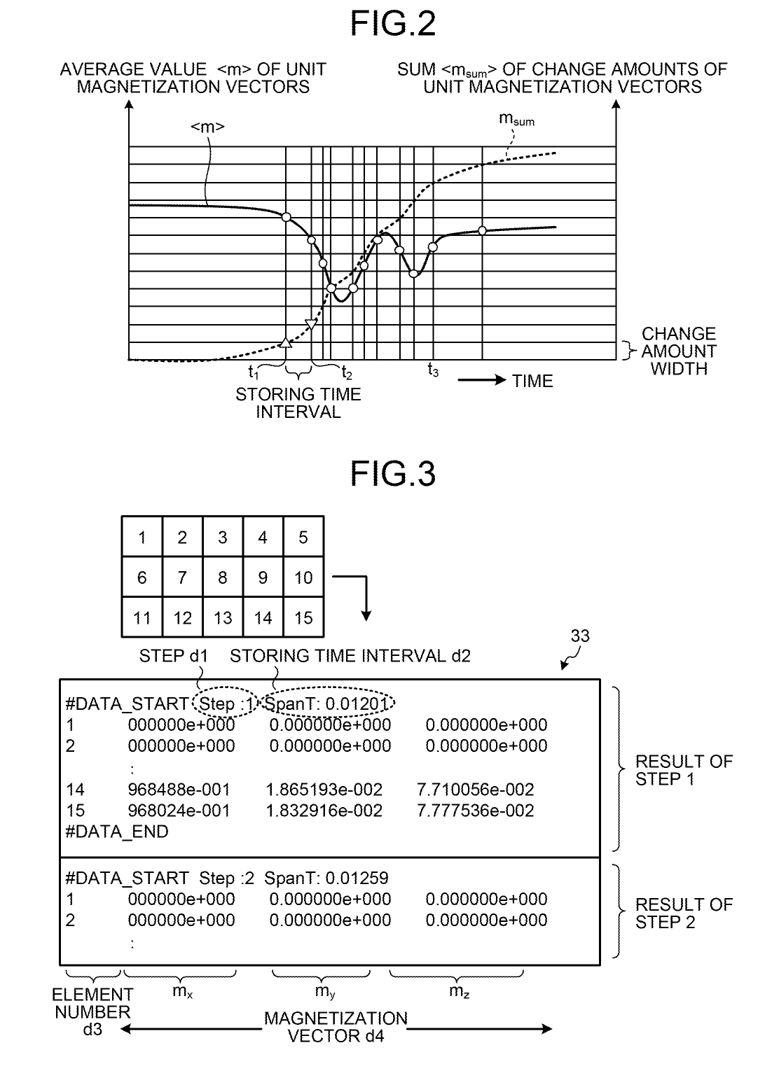

The timing at which the unit magnetization vectors are stored will be described with reference to FIG. 2. FIG. 2 is a graph for explaining the unit magnetization vector, the sum of the change amounts, and the storing timing. Line graphs as illustrated in FIG. 2 are illustrated while the X-axis indicates time and the Y-axis indicates the average value <m> of the unit magnetization vectors and the sum <mₛᵤₘ> of the change amounts of the unit magnetization vectors. A solid curve indicates the average value <m> of the unit magnetization vectors over the time. A dashed curve indicates the sum <mₛᵤₘ> of the change amounts of the unit magnetization vectors that change from moment to moment over the time.

The sum <mₛᵤₘ> of the change amounts of the unit magnetization vectors is expressed by the equation (4). As the average value <m> of the unit magnetization vectors, the average value of the unit magnetization vectors arranged on all the elements (nodal points, or the like) j at the time point i is expressed by an equation (5).

$${〈 m 〉}^{i} = {\sum }_{j = 1}^{N} {m}_{j}^{i} \qquad ( 5 )$$

Furthermore, horizontal auxiliary lines are illustrated at a constant interval for an axis indicating the sum of the change amounts. The interval of the horizontal auxiliary lines corresponds to the change amount width.

Under this condition, the change amount determination unit 43 determines whether the sum obtained by cumulating the change amounts of the unit magnetization vectors at the respective time points by the change amount cumulating unit 42 exceeds the change amount width. Then, when the change amount determination unit 43 determines that the sum exceeds the change amount width, the storing unit 44 stores, in the result data 33, the unit magnetization vectors at the time point at which the sum exceeds the change amount width and the period of time (storing time interval) from the time point at which the sum exceeds the change amount width at the previous time to the time point at which the sum exceeds the change amount width at this time in a correspondence manner.

As an example, the change amount determination unit 43 determines that the sum of the change amounts of the unit magnetization vectors at a time point t1 exceeds the change amount width (indicated by Δ). Accordingly, the storing unit 44 stores, in the result data 33, the unit magnetization vectors at the time point t1 at which the sum exceeds the change amount width and a storing time interval t1 from a calculation starting time 0 to the time point t1 at which the sum exceeds the change amount width at this time in a correspondence manner. As another example, the change amount determination unit 43 determines that the sum of the change amounts of the unit magnetization vectors at a time point t2 exceeds the change amount width (indicated by V). Accordingly, the storing unit 44 stores, in the result data 33, the unit magnetization vectors at the time point t2 at which the sum exceeds the change amount width and a storing time interval (t2−t1) from the time point t1 at which the sum exceeds the change amount width at the previous time to the time point t2 at which the sum exceeds the change amount width at this time in a correspondence manner.

That is to say, perpendicular auxiliary lines are generated so as to pass through points at which the horizontal auxiliary lines indicating the change amount width and the curve indicating the sum of the change amounts intersect with each other. Time points (for example, t1 and t2) corresponding to the generated perpendicular auxiliary lines are time points at which the unit magnetization vectors are stored. Intersections (indicated by ◯) of the perpendicular auxiliary lines indicating the time points and the curve indicating the average value of the unit magnetization vectors are average values <m> of the unit magnetization vectors at the time points at which the unit magnetization vectors are stored.

With this, the storing unit 44 can prevent pieces of data of the magnetization vectors from being stored wastefully in time regions (for example, 0 to t1 and t3 to . . . ) in which the magnetization vectors do not change largely because change in the value of the magnetization vector is small. On the other hand, the storing unit 44 can store the sufficient number of pieces of data of the magnetization vectors in time regions (for example, t1 to t3) in which the magnetization vectors change largely. That is to say, the storing unit 44 can store the pieces of data of the magnetization vectors in accordance with the change amount of the magnetization vectors.

Example of Calculation Data

An example of the result data 33 that is stored by the storing unit 44 will be described with reference to FIG. 3. FIG. 3 is a view illustrating the example of the result data 33. In an upper view of FIG. 3, the mesh data 31 of the magnetic body as the analysis target is illustrated. The mesh data 31 is formed by a plurality of elements obtained by dividing a region of the magnetic body as the analysis target into 15. The magnetization vectors are arranged at the centers of the respective elements. In the result data 33 of the transient calculation using this model, pieces of information about the magnetization vectors for 15 elements and the storing time interval are stored at each time point of the storing timing.

A lower view of FIG. 3 illustrates an example of the result data 33. The result data 33 contains a step d1, a storing time interval d2, an element number d3, and a magnetization vector d4. The step d1 indicates an identification number of pieces of information that are stored at each time point of the storing timing and is assigned in the ascending order. The storing time interval d2 indicates a period of time from the time point at which the sum exceeds the change amount width at the previous time to the time point at which the sum exceeds the change amount width at this time. The element number d3 indicates the number of the element. The respective numbers as the element number d3 correspond to respective values of the index j in the equations (1) to (5). The magnetization vector d4 indicates a value of the magnetization vector corresponding to the number indicated by the element number d3. For example, the magnetization vector d4 is indicated by a value (mₓ) of an x component, a value (m_{y}) of a y component, and a value (m_{z}) of a z component.

As an example, when the step (Step) d1 is “1”, “0.01201” is stored as the storing time interval (SpanT) d2. When the element number d3 is “1”, the x component of “000000e+000”, the y component of “000000e+000”, and the z component of “000000e+000” are stored as the magnetization vector d4. When the element number d3 is “15”, the x component of “968024e−001”, the y component of “1.832916e−002”, and the z component of “7.777536e−002” are stored as the magnetization vector d4.

Returning back to FIG. 1, the result output unit 45 outputs the magnetization vectors using the result data 33 stored in the storage unit 30. For example, the result output unit 45 outputs the magnetization vectors corresponding to the storing time interval after making them into a sleep state for the storing time interval in the result data 33 in the order they are stored in the storage unit 30. To be specific, the result output unit 45 makes the magnetization vectors into the sleep state for a period of time of a coefficient multiple of the storing time interval between a frame and a frame on which the magnetization vectors are drawn continuously. Then, the result output unit 45 arranges the magnetization vectors on the corresponding mesh contained in the mesh data 31 and outputs them. This enables the result output unit 45 to visualize the magnetization vectors corresponding to actual physical behaviors of the magnetization vectors.

Flowchart of Magnetization Vector Storing Processing

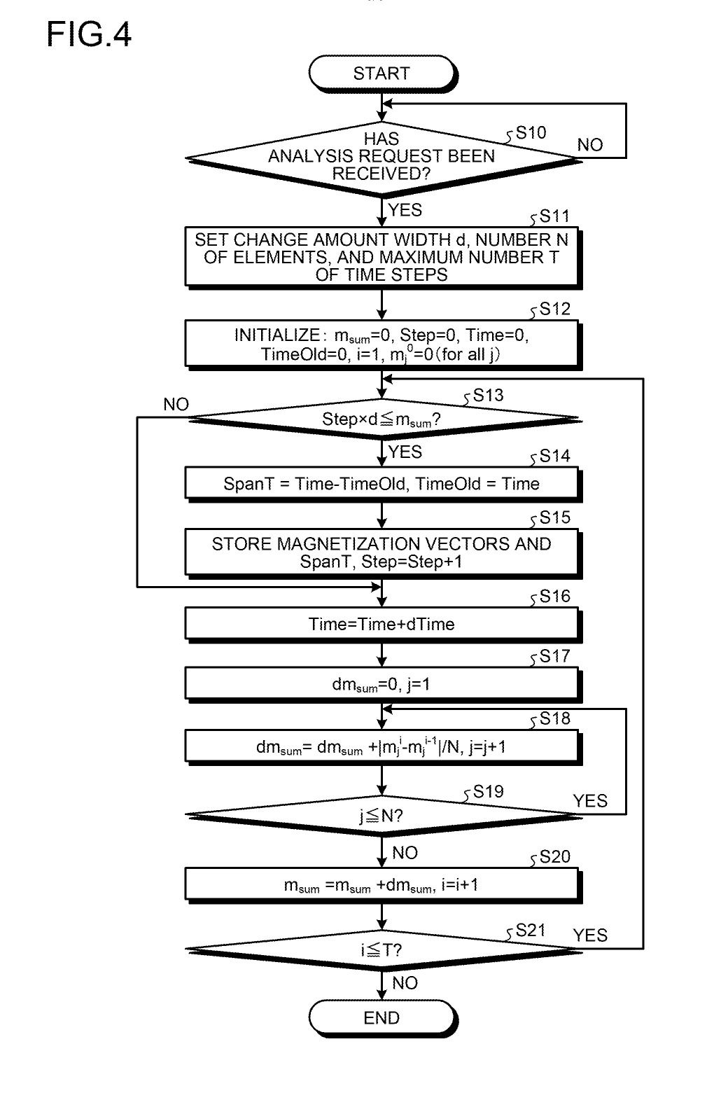

Next, a flowchart of magnetization vector storing processing will be described with reference to FIG. 4. FIG. 4 is a view illustrating the flowchart of the magnetization vector storing processing in the embodiment.

First, the controller 40 determines whether it has received an analysis request (step S10). If the controller 40 determines that it has not received the analysis request (No at step S10), the controller 40 repeats the determination processing until it receives the analysis request.

If the controller 40 determines that it has received the analysis request (Yes at step S10), the controller 40 sets a change amount width d, the number N of elements on which the magnetization vectors are arranged, and the maximum number T of time steps (step S11). For example, the controller 40 sets the change amount width, the number of elements on which the magnetization vectors are arranged, and the maximum number of time steps that have been input from the input unit 10 to the respective variables.

Subsequently, the controller 40 initializes the respective variables to be used for the analysis (step S12). For example, the controller 40 sets a variable mₛᵤₘ to be used for setting the sum of the change amounts of the magnetization vectors to 0. The controller 40 sets Step to be used for setting the step to 0. The step referred herein indicates the identification number that is set for each time point of the storing timing and corresponds to the step d1 in the result data 33. The controller 40 sets Time to be used for managing time in the analysis to 0. The controller 40 sets TimeOld to be used for setting the time point at which the sum exceeds the change amount width at the previous time to 0. The controller 40 sets i to be used for setting the time step to 1. The time step i is an index corresponding to the storing time. The controller 40 sets 0 to values mⱼ⁰ of the magnetization vectors of all the elements j when the time step i is 0.

Thereafter, the change amount determination unit 43 determines whether the variable mₛᵤₘ to be used for setting the sum of the change amounts of the magnetization vectors is equal to or larger than a value obtained by multiplying Step to be used for setting the step by the change amount width d (step S13). That is to say, the change amount determination unit 43 determines whether the sum obtained by cumulating the change amounts of the magnetization vectors is equal to or larger than the change amount width. It is to be noted that the change amount cumulating unit 42 calculates the variable mₛᵤₘ, that is, the sum obtained by cumulating the change amounts of the magnetization vectors.

If it is determined that the variable mₛᵤₘ is smaller than the value obtained by multiplying Step by the change amount width d (No at step S13), the change amount determination unit 43 moves the process to step S16 in order to advance the time.

If it is determined that the variable mₛᵤₘ is equal to or larger than the value obtained by multiplying Step by the change amount width d (Yes at step S13), the storing unit 44 sets a value obtained by subtracting the time point TimeOld at which the sum exceeds the change amount width at the previous time from the time point Time at which the sum exceeds the change amount width at this time to SpanT as the storing time interval. Then, the storing unit 44 sets the time point Time at which the sum exceeds the change amount width at this time to the time point TimeOld at which the sum exceeds the change amount width at the previous time (step S14).

The storing unit 44 stores, in the result data 33, the magnetization vectors at the time point at which the sum exceeds the change amount width at this time and the storing time interval SpanT. In addition, the storing unit 44 stores a value set to Step in the result data 33. Furthermore, the storing unit 44 adds 1 to Step (step S15). Then, the storing unit 44 moves the process to step S16 in order to advance the time.

At step S16, the change amount calculation unit 41 adds the time interval width dTime to the variable Time to be used for managing time (step S16).

Subsequently, the change amount calculation unit 41 sets 0 to the change amount dmₛᵤₘ of the magnetization vectors at the time step i for initialization. The change amount calculation unit 41 sets 1 to the element j (step S17). The change amount calculation unit 41 calculates the change amount dmₛᵤₘ of the magnetization vectors at the time step i as follows. That is to say, the change amount calculation unit 41 adds an average value of absolute values of change amounts of the magnetization vector on the element j at the present time step i and at the previous time step i−1 to dmₛᵤₘ. Then, the change amount calculation unit 41 adds 1 to the element j (step S18).

The change amount calculation unit 41 determines whether the element j is equal to or smaller than N as the maximum number of the elements (step S19). If it is determined that the element j is equal to or smaller than N as the maximum number of the elements (Yes at step S19), the change amount calculation unit 41 moves the process to step S18 in order to calculate the change amount of the subsequent element j.

If it is determined that the element j is larger than N as the maximum number of the elements (No at step S19), the change amount cumulating unit 42 adds the change amount dmₛᵤₘ of the magnetization vectors at the time step i to the sum mₛᵤₘ of the change amounts of the magnetization vectors. Then, the change amount cumulating unit 42 adds 1 to the time step i (step S20). That is to say, the change amount cumulating unit 42 adds the change amount of the magnetization vectors calculated by the change amount calculation unit 41 to the sum of the change amounts of the magnetization vectors calculated before.

Thereafter, the change amount cumulating unit 42 determines whether the time step i is equal to or smaller than the maximum number T of the time steps (step S21). If it is determined that the time step i is equal to or smaller than the maximum number T of the time steps (Yes at step S21), the change amount cumulating unit 42 moves the process to step S13 in order to determine the change amount.

If it is determined that the time step i is larger than the maximum number T of the time steps (No at step S21), the controller 40 finishes the magnetization vector storing processing.

Flowchart of Result Output Processing

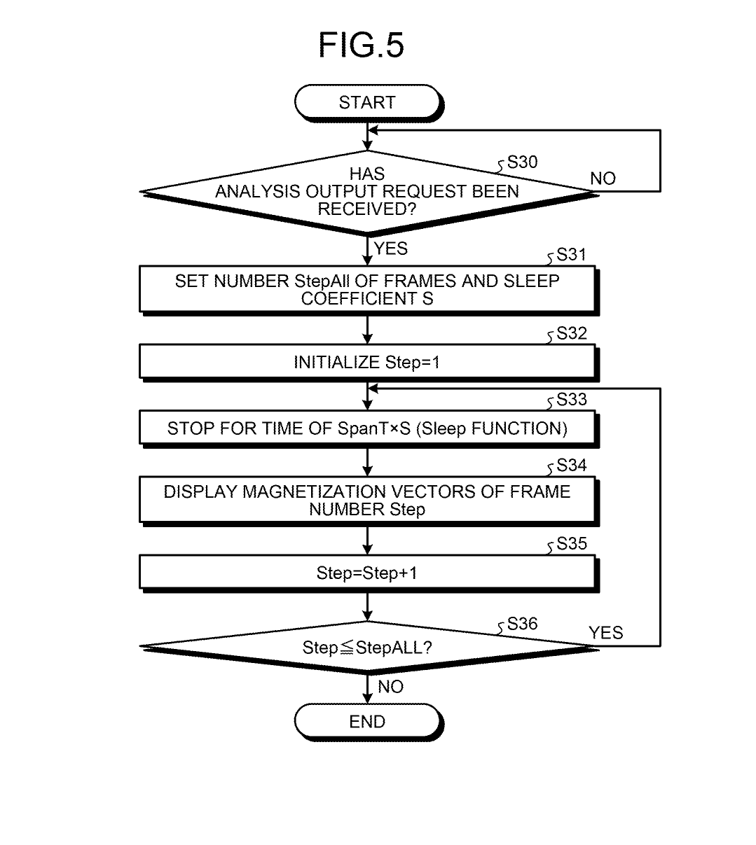

Next, the flowchart of result output processing will be described with reference to FIG. 5. FIG. 5 is a view illustrating the flowchart of the result output processing in the embodiment.

First, the controller 40 determines whether it has received an analysis output request (step S30). If the controller 40 determines that it has not received the analysis output request (No at step S30), the controller 40 repeats the determination processing until it receives the analysis output request.

If the controller 40 determines that it has received the analysis output request (Yes at step S30), the result output unit 45 sets the number StepAll of frames that are output as a result and a sleep coefficient S to be used for achieving the sleep state between the frames (step S31). For example, the result output unit 45 sets the number of frames to be output and the sleep coefficient that have been input from the input unit 10 to the respective variables. The input unit 10 inputs the number of frames to be output that does not exceed the maximum number of steps set as the steps d1 in the result data 33.

Subsequently, the result output unit 45 initializes the variables to be used for outputting the result (step S32). For example, the result output unit 45 sets 1 to the variable Step that is used as the frame number to be output.

Then, the result output unit 45 reads the result data 33 and visualizes the magnetization vectors in Step that is indicated as the frame number. The Step referred herein corresponds to the step d1 in the result data 33. The result output unit 45 stops outputting of the result corresponding to a value identical to Step among values indicated as the step d1 in the result data 33 for time SpanT indicated as the storing time interval d2 using a Sleep function (step S33).

Subsequently, the result output unit 45 displays the magnetization vectors as the magnetization vector d4 for the elements as the element number d3 on the display unit 20 for the result corresponding to the value identical to Step among the values indicated as the step d1 in the result data 33 (step S34). It is to be noted that the result output unit 45 may display the magnetization vectors of any one of the X-axis component, the Y-axis component, and the Z-axis component. Alternatively, the result output unit 45 may display the magnetization vectors of any two of the X-axis component, the Y-axis component, and the Z-axis component or display the magnetization vectors of all the components collectively.

Then, the result output unit 45 adds 1 to the variable Step to be used as the frame number (step S35). The result output unit 45 determines whether the variable Step is equal to or smaller than StepAll indicating the number of frames (step S36). If it is determined that the variable Step is equal to or smaller than StepAll indicating the number of frames (Yes at step S36), the result output unit 45 moves the process to step S33 in order to output the subsequent frame.

If it is determined that the Step is larger than StepAll indicating the number of frames (No at step S36), the result output unit 45 finishes the result output processing.

Example of Result Output

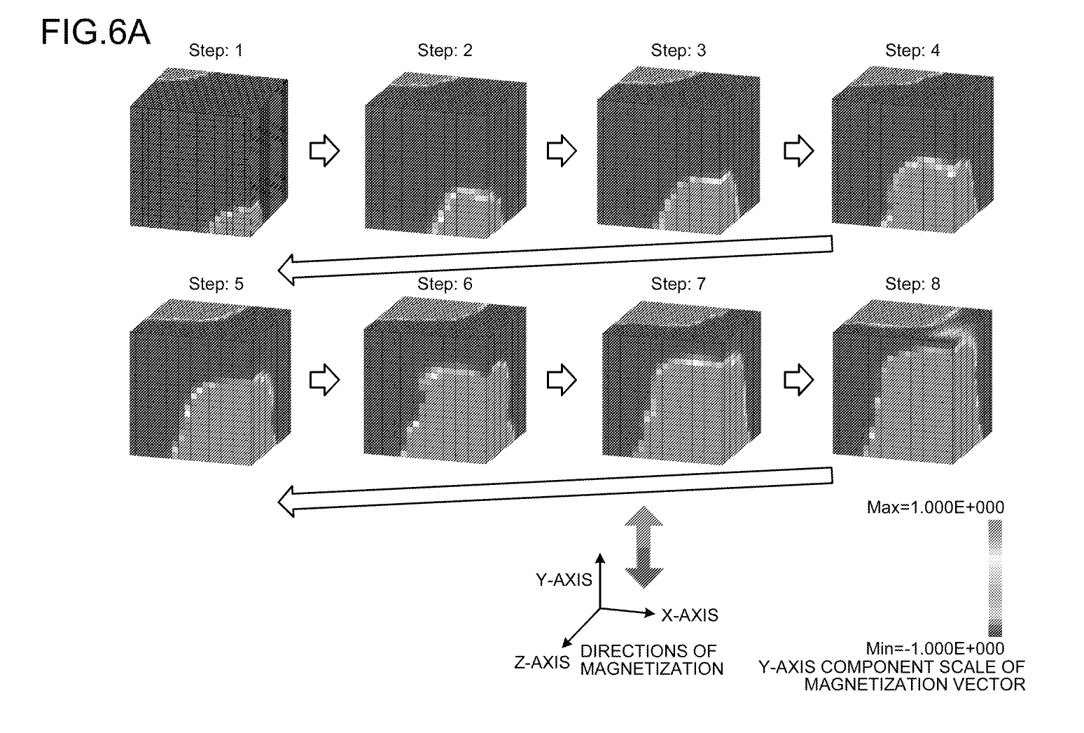

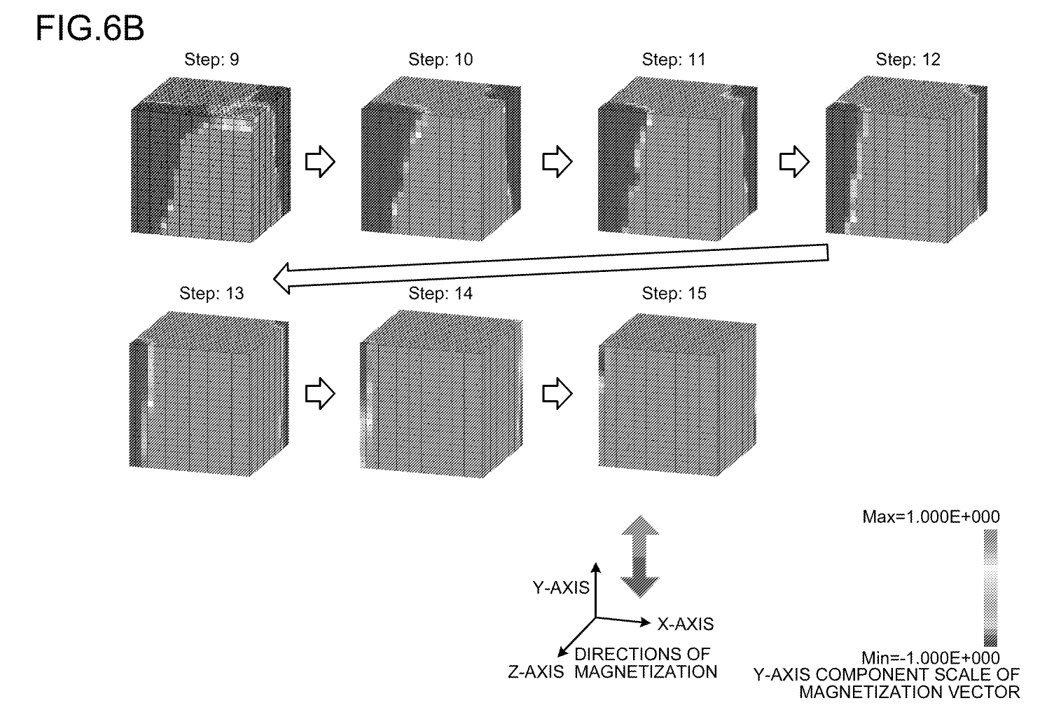

Next, FIG. 6A and FIG. 6B illustrate an example of the result output by the result output unit 45. FIG. 6A and FIG. 6B are views illustrating an example of transition of magnetization change of the magnetization vectors (Y-axis component). The magnetization vectors of the plurality of elements are set for the number of (in this example, 15) time steps in the result data 33.

As illustrated in FIG. 6A and FIG. 6B, the result output unit 45 outputs the magnetization vectors of the Y component as the magnetization vector d4 using the result of Step 1 set in the result data 33. The magnetization vectors of the Y component as the magnetization vector d4 are output for the elements of all the numbers set to the element number d3. The result output unit 45 makes the magnetization vectors into the sleep state for a period of time of a coefficient multiple of the storing time interval d2 using the result of Step 1. Then, the result output unit 45 outputs the magnetization vectors of the Y component that are arranged on the centers of the respective elements.

Next, the result output unit 45 outputs the magnetization vectors of the Y component as the magnetization vector d4 using the result of Step 2 set in the result data 33. The magnetization vectors of the Y component as the magnetization vector d4 are output for the elements of all the numbers set to the element number d3. The result output unit 45 makes the magnetization vectors into the sleep state for a period of time of the coefficient multiple of the storing time interval d2 using the result of Step 2. Then, the result output unit 45 outputs the magnetization vectors of the Y component that are arranged on the centers of the respective elements.

In this manner, the result output unit 45 outputs the magnetization vectors for 15 time steps in the descending order of the value of the step d1 set in the result data 33. With this, the result output unit 45 can visualize the magnetization vectors in proportion to the change speed of the actual physical behaviors of the magnetization vectors.

Effect of Embodiment

With the above-mentioned embodiment, the magnetic body analyzing device 1 calculates a change amount by which magnetization vectors arranged on an analysis target have changed for a predetermined period of time every time the predetermined period of time passes when a magnetic body is analyzed. Then, the magnetic body analyzing device 1 cumulates respective change amounts of the magnetization vectors calculated for each predetermined period of time every time the predetermined period of time passes. The magnetic body analyzing device 1 determines whether the cumulated value of the change amounts of the magnetization vectors cumulated exceeds a predetermined change amount width. When it is determined that the cumulated value of the change amounts of the magnetization vectors exceeds the predetermined change amount width, the magnetic body analyzing device 1 records, in the storage unit 30, the magnetization vectors at a time point at which the cumulated value exceeds the predetermined change amount width as the result data 33. With this configuration, the magnetic body analyzing device 1 stores the magnetization vectors in accordance with the change amounts of the magnetization vectors, thereby improving storing efficiency of the magnetization vectors. That is to say, the magnetic body analyzing device 1 can prevent the magnetization vectors from being stored wastefully in a period of time in which the magnetization vectors do not change largely. On the other hand, the magnetic body analyzing device 1 can store the magnetization vectors for a short period of time in the period of time in which the magnetization vectors change largely, thereby storing the magnetization vectors that change moment to moment.

When the magnetization vectors at the time point at which the cumulated value exceeds the change amount width have been recorded in the storage unit 30, the magnetic body analyzing device 1 determines whether the cumulated value of the change amounts of the magnetization vectors after the time point at which the cumulated value exceeds the predetermined change width exceeds the change width newly. When it is determined that the cumulated value exceeds the change width, the magnetic body analyzing device 1 records, in the storage unit 30, the magnetization vectors at the time point at which the cumulated value exceeds the change width and a period of time from the time point at which the cumulated value exceeds the change width at the previous time to the time point at which the cumulated value exceeds the change width at this time in a correspondence manner. With this configuration, the magnetic body analyzing device 1 can store the magnetization vectors that change moment to moment in accordance with the change amounts of the magnetization vectors.

Furthermore, the magnetic body analyzing device 1 outputs the magnetization vectors corresponding to each period of time after making them into a sleep state for the period of time in the order they are recorded using the magnetization vectors and the period of time for each recording that have been recorded in the storage unit 30. With this configuration, the magnetic body analyzing device 1 can visualize change of the magnetic field of the actual physical phenomenon by making the magnetization vectors into the sleep state for the period of time in the recorded order.

In addition, the magnetic body analyzing device 1 calculates an average value of the absolute values of the change amounts of the magnetization vectors as the change amount of the magnetization vectors using respective change amounts of the magnetization vectors arranged on the respective elements obtained by dividing the analysis target every time the predetermined period of time passes. With this configuration, the change amounts of the magnetization vectors on the analysis target are calculated using the magnetization vectors on the respective elements obtained by dividing the analysis target at the respective time points. This enables the change amount of the magnetization vector to be calculated with high accuracy as the number of elements is increased.

Others

In the above-mentioned embodiment, the magnetic body analyzing device 1 reads the mesh data 31 and the calculation condition data 32 from the storage unit 30, starts calculation, and stores the result data 33 of the magnetization vectors in the storage unit 30 in the process of transient calculation. Alternatively, the magnetic body analyzing device 1 may acquire the mesh data 31 and the calculation condition data 32 from a storage device connected to the magnetic body analyzing device 1, start calculation, and store the result data 33 of the magnetization vectors in the storage unit 30 in the process of transient calculation. Furthermore, the magnetic body analyzing device 1 may receive the mesh data 31 and the calculation condition data 32 through a network, start calculation, and store the result data 33 of the magnetization vectors in the storage unit 30 in the process of transient calculation.

The constituent components of the magnetic body analyzing device 1 as illustrated in the drawings do not always need to be configured as illustrated in the drawings physically. That is to say, specific forms of disintegration and integration of the magnetic body analyzing device 1 are not limited to those as illustrated in the drawings, and all of or a part of them can be configured to be disintegrated or integrated functionally or physically based on an arbitrary unit depending on various loads and usage conditions. For example, the change amount calculation unit 41 and the change amount cumulating unit 42 may be integrated as one unit. Furthermore, the storage unit 30 may be connected through a network as an external device of the magnetic body analyzing device 1.

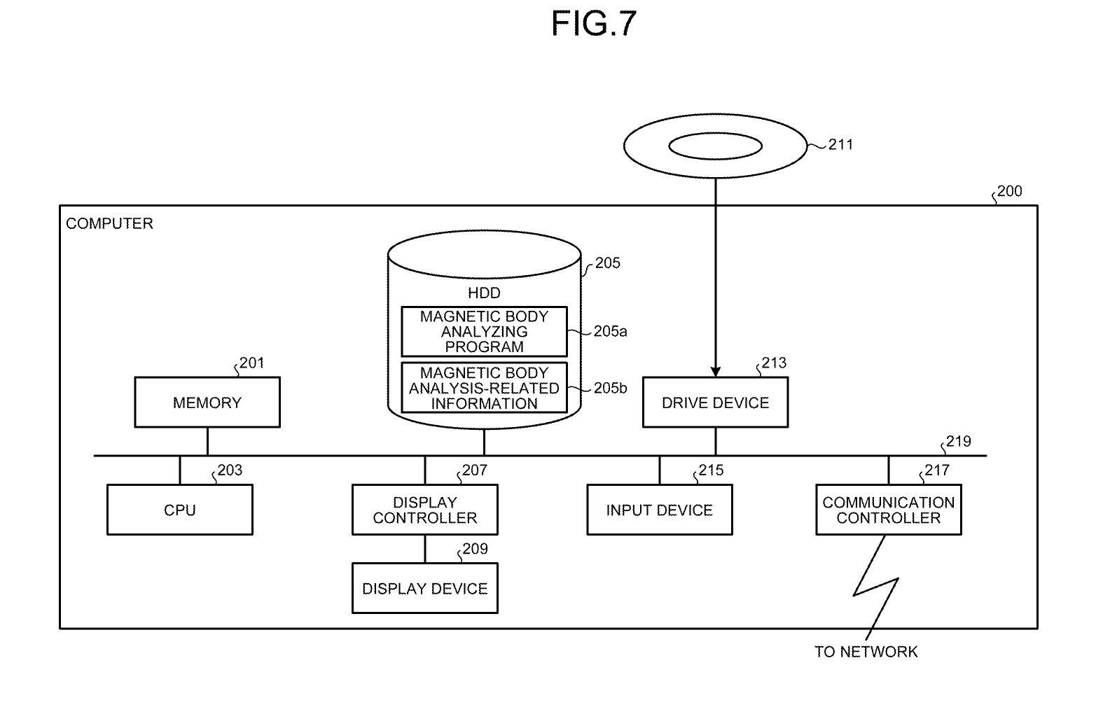

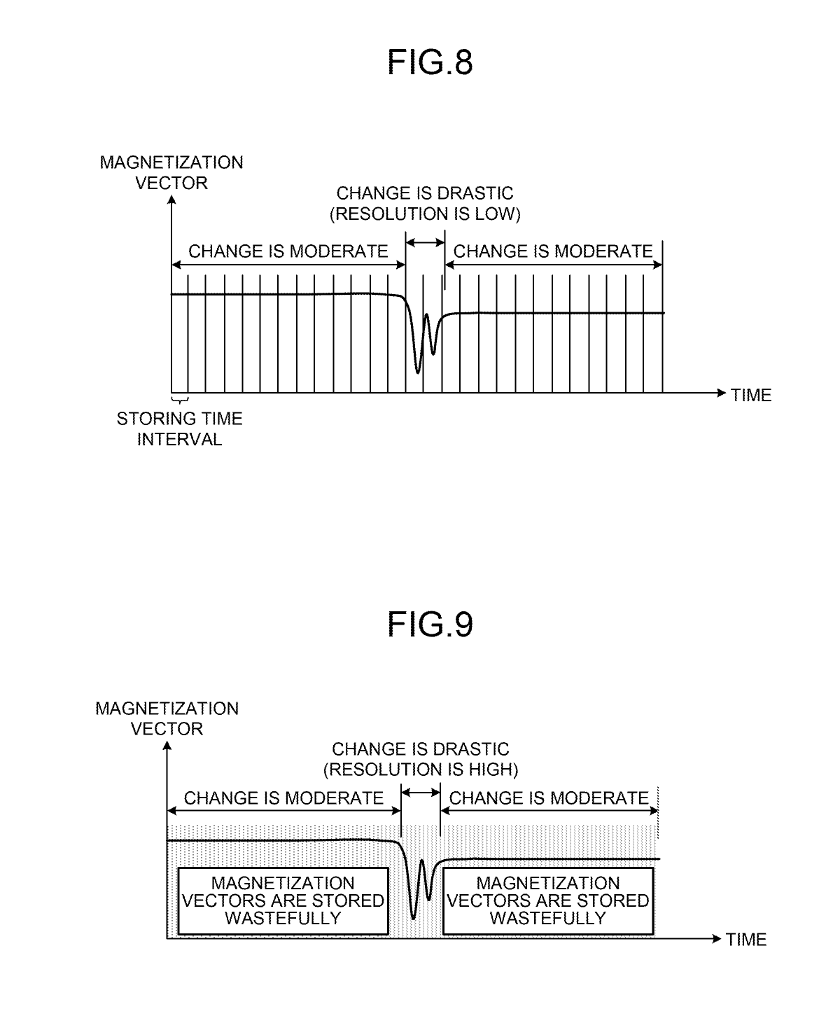

The various pieces of processing as described in the above-mentioned embodiment can be achieved by executing a previously prepared computer program by a computer such as a personal computer and a workstation. The following describes an example of a computer executing the magnetic body analyzing program that achieves the functions same as those of the magnetic body analyzing device 1 as illustrated in FIG. 1. FIG. 7 is a diagram illustrating an example of the computer executing the magnetic body analyzing program.

As illustrated in FIG. 7, a computer 200 includes a central processing unit (CPU) 203 executing various pieces of arithmetic processing, an input device 215 receiving input of data from a user, and a display controller 207 controlling a display device 209. The computer 200 includes a drive device 213 reading computer programs and the like from a storage medium and a communication controller 217 transmitting and receiving data to and from another computer through a network. The computer 200 includes a memory 201 storing various pieces of information temporarily and a hard disk drive (HDD) 205. The memory 201, the CPU 203, the HDD 205, the display controller 207, the drive device 213, the input device 215, and the communication controller 217 are connected to one another through a bus 219.

The drive device 213 is a device for a removable disk 211, for example. The HDD 205 stores therein a magnetic body analyzing program 205a and magnetic body analysis-related information 205b.

The CPU 203 reads the magnetic body analyzing program 205a, develops it on the memory 201, and executes it as a process. The process corresponds to the respective functional units of the magnetic body analyzing device 1. The magnetic body analysis-related information 205b corresponds to the mesh data 31, the calculation condition data 32, and the result data 33. For example, the removable disk 211 stores therein respective pieces of information such as the magnetic body analyzing program 205a.

It is to be noted that the magnetic body analyzing program 205a need not be stored in the HDD 205 initially. For example, the magnetic body analyzing program 205a is stored in a “mobile physical medium” such as a flexible disk (FD), a compact disc read-only memory (CD-ROM), a digital versatile disc (DVD), a magnet-optical disk, and an integrated circuit (IC) card that is inserted into the computer 200. Then, the computer 200 may read out the magnetic body analyzing program 205a from the “mobile physical medium” and execute it.

A storage efficiency of the magnetization vectors that are used in the magnetic body analysis can be improved.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A magnetic body analyzing device comprising:
a processor; and
a memory, wherein the processor executes:
calculating a change amount by which magnetization vectors arranged on an analysis target change for a predetermined period of time every time the predetermined period of time passes when a magnetic body is analyzed;
cumulating respective change amounts of the magnetization vectors calculated for each predetermined period of time at the calculating every time the predetermined period of time passes;
determining whether a cumulated value of the change amounts of the magnetization vectors cumulated at the cumulating exceeds a predetermined change width; and
recording, in the memory, the magnetization vectors of a time point at which the cumulated value exceeds the change width when the determining determines that the cumulated value exceeds the change width.

2. The magnetic body analyzing device according to claim 1, wherein
the determining determines whether a cumulated value of change amounts of magnetization vectors, after the time point at which the cumulated value exceeds the change width, exceeds the change width newly, when the recording records, in the memory, the magnetization vectors of the time point at which the cumulated value exceeds the change width, and
the recording records, in the memory, the magnetization vectors of the time point at which the cumulated value exceeds the change width and a period of time from a time point at which the cumulated value exceeds the change width at a previous time to the time point at which the cumulated value exceeds the change width at this time in a correspondence manner, when the determining determines that the cumulated value exceeds the change width.

3. The magnetic body analyzing device according to claim 2, the processor further executes:
outputting magnetization vectors corresponding to the period of time after making the magnetization vectors into a sleep state for the period of time in a recorded order, using the magnetization vectors and the period of time for each recording that are recorded in the memory.

4. The magnetic body analyzing device according to claim 1, wherein the calculating calculates an average value of absolute values of change amounts of the magnetization vectors, using respective change amounts of the magnetization vectors arranged on respective elements obtained by dividing the analysis target every time the predetermined period of time passes.

5. A non-transitory computer-readable recording medium having stored therein a program for causing a computer to execute a magnetic body analyzing process comprising:
calculating a change amount by which magnetization vectors arranged on an analysis target change for a predetermined period of time every time the predetermined period of time passes when a magnetic body is analyzed;
cumulating respective change amounts of the magnetization vectors calculated for each predetermined period of time at the calculating every time the predetermined period of time passes;
determining whether a cumulated value of the change amounts of the magnetization vectors cumulated at the cumulating exceeds a predetermined change width; and
recording, in a storage unit, the magnetization vectors of a time point at which the cumulated value exceeds the change width when it is determined that the cumulated value exceeds the change width at the determining.

6. A method for analyzing a magnetic body on a computer, the method comprising:
calculating a change amount by which magnetization vectors arranged on an analysis target change for a predetermined period of time every time the predetermined period of time passes when a magnetic body is analyzed using a processor;
cumulating respective change amounts of the magnetization vectors calculated for each predetermined period of time at the calculating every time the predetermined period of time passes using the processor;
determining whether a cumulated value of the change amounts of the magnetization vectors cumulated at the cumulating exceeds a predetermined change width using the processor; and
recording, in a storage unit, the magnetization vectors of a time point at which the cumulated value exceeds the change width when it is determined that the cumulated value exceeds the change width at the determining using the processor.
